(19) United States
(12) Patent Application Publication
(10) Pub. No.: US 2022/0068614 A1
(43) Pub. Date: Mar. 3, 2022

(54) SEMICONDUCTOR MANUFACTURING MEMBER AND MANUFACTURING METHOD THEREFOR

(71) Applicant: CoorsTek KK, Tokyo (JP)

(72) Inventors: Masahiko ICHISHIMA, Kanagawa (JP); Hiroshi OISHI, Kanagawa (JP); Noriko OMORI, Kanagawa (JP); Akira MIYAZAKI, Kanagawa (JP); Masahiro KUBOTA, Kanagawa (JP); Jun KOMIYAMA, Kanagawa (JP)

(73) Assignee: CoorsTek KK

(21) Appl. No.: 17/409,587

(22) Filed: Aug. 23, 2021

(30) Foreign Application Priority Data
Aug. 28, 2020 (JP) 2020-144771
Jun. 11, 2021 (JP) 2021-097822

(51) Int. Cl. H01J 37/32; H01L 21/687; C23C 4/10; C23C 4/18

(52) U.S. Cl. CPC H01J 37/32642; H01L 21/68721; H01J 2237/334; C23C 4/10; C23C 4/185; H01L 21/68757

(57) ABSTRACT

The present invention relates to a semiconductor manufacturing member including a silicon carbide-containing boron carbide film at least on a surface thereof, in which the silicon carbide-containing boron carbide film has a content of silicon carbide of 5 wt % or more and 18 wt % or less and a balance being boron carbide.

### TECHNICAL FIELD

The present invention relates to a semiconductor manufacturing member and a manufacturing method therefor. For example, the present invention relates to a semiconductor manufacturing member suitable for a focus ring used in a plasma processing apparatus, and a manufacturing method therefor.

### BACKGROUND ART

In a semiconductor device manufacturing process, a plasma processing apparatus such as a plasma etching apparatus or a plasma CVD apparatus is used, and a process such as etching is performed on a to-be-processed substrate. At that time, in order to allow plasma processing of the to-be-processed substrate to be uniform, a focus ring is arranged as a semiconductor manufacturing member so as to surround the to-be-processed substrate.

The focus ring is provided on an outside of the to-be-processed substrate, and for example, by mounting the to-be-processed substrate in the inner peripheral portion thereof, a so-called pseudo-to-be-processed substrate (pseudo-wafer) is formed around the to-be-processed substrate, and thus, the plasma processing of the to-be-processed substrate (wafer) is uniformly conducted.

The focus ring is generally made of silicon and is formed in a ring shape having an outer diameter larger than the to-be-processed substrate. Specifically, with respect to the focus ring, for example, a ring-shaped focus ring is produced by cutting out a disk-shaped member from a single crystal silicon ingot and further removing a central portion of the disk-shaped member.

By the way, as described above, in the related art, the focus ring is produced by processing the silicon ingot into a ring shape, but in the future, boron carbide (B₄C) is expected as a material having a long lifetime.

Since the boron carbide does not easily react with oxygen-free fluorine-based and chlorine-based corrosive gases or oxygen-free plasma, the boron carbide has excellent corrosion resistance. Furthermore, even when the boron carbide reacts with fluorine or chlorine, a reactant having a high vapor pressure is generated, so that the boron carbide is released to the outside of the system as a gas without generating particles.

Patent Document 1 describes that the boron carbide is desirably configured with a sintered body having a relative density of 98% or more. This is because, when the material has a large number of pores with a low density, the contact area with the corrosive gas or the plasma increases accordingly, and thus, the consumption of the boron carbide becomes fast. For this reason, the boron carbide preferably has a relative density of 98% or more, particularly 99% or more and is required to be a dense material having an open porosity of 0.2% or less.

In addition, according to Patent Document 1, as the diameter of a silicon wafer is increased, the manufacturing apparatus and the components themselves are also increased in size, and thus it is desirable to have a transverse strength of 300 MPa or more to maintain the durability as a component.

According to the manufacturing method disclosed in Patent Document 1, for example, a sintered body of boron carbide is obtained in such a manner that a boron carbide powder having an average particle size of 20 μm or less is filled in a mold or formed into a desired shape, and hot pressing is performed in a non-oxidizing atmosphere at 2100 to 2300° C.

In addition, in Patent Document 1 describes that sintering can be performed at a lower temperature in a non-oxidizing atmosphere or in a vacuum with addition of a sintering additive such as carbon (C), SiC, or Si₃N₄, and the molded body or the sintered body can be further densified by heat-treating in an inert atmosphere of 1000 atm or more by hot isostatic pressing sintering.
Patent Document 1: JP-A-H11-102900

### SUMMARY OF INVENTION

By the way, in a recent dry etching technology, oxygen plasma etching, Ar plasma etching, fluorine-based plasma etching, or the like is used, and a very high frequency power is applied.

For example, in general, a resist pattern is formed by a lithography technique before performing anisotropic processing on a to-be-processed substrate by a dry etching technology. The resolution of the 193 nm ArF immersion device is 38 nm, but the multi-patterning technique exceeds the resolution limit, so that a pattern of 10 to 7 nm is implemented.

In addition, as a general method of double patterning, a sidewall process using a residue of a pattern side wall formed after dry etching is employed. Specifically, an amorphous carbon layer, an SiON layer, an antireflection film layer, and a resist pattern by ArF immersion exposure are formed on an SiN film to which a line pattern is to be finally formed.

Then, the resist pattern is shrunk by isotropic etching with oxygen plasma, and the antireflection film, the SiON film, and the amorphous carbon layer are dry-etched in this order to form a carbon pattern. When an atomic layer deposition (ALD) film is deposited on the carbon pattern and then dry etching is performed, a sidewall which is an etching residue is generated on the side wall of the carbon pattern. When carbon is removed, only the sidewall remains. When the SiN film is dry-etched by using the sidewall as a mask and then the mask is removed, an extremely fine line pattern is formed.

In addition, it is necessary to machine a very deep hole for a capacitor of a DRAM or a memory hole for a three-dimensional NAND. In order to form such a fine hole having a high aspect ratio, a highly accurate anisotropic shape and a high selection ratio for the mask and the base film are required.

For this reason, a fluorocarbon-based gas is used as the etching gas, and a method of performing vertical etching by pulling ions such as CFx+ and Ar+ vertically into a hole of an SiO₂ film by RF bias while depositing a polymerized film on the side wall of the hole of the mask and the SiO₂ film as a side wall protective film by CFx radicals is employed.

In addition, when the hole becomes deep, the reaction product may not be exhausted well and may accumulate on the bottom of the hole, which may cause etch stop. In that case, a method called “O₂ flash” of removing the reaction product by oxygen plasma etching is employed.

In order to increase the etching rate of the SiO₂ film, an increase in the incident amount of ions, an increase in the total amount of F in the radicals, and sufficient ion energy are necessary. For this reason, a high-frequency power for plasma generation, a flow rate of fluorocarbon gas, a high-frequency power for ion attraction, and the like are adjusted.

As described above, in the recent dry etching technology, oxygen plasma etching, Ar plasma etching, fluorine-based plasma etching, or the like is used, and a very high-frequency power is applied.

However, when the focus ring (semiconductor manufacturing member) of the plasma processing apparatus is made of a boron carbide material, the boron carbide does not easily react with oxygen-free fluorine and chlorine-based corrosive gases or plasma, but when the plasma contains oxygen (in the case of oxygen plasma), a problem arises in that the corrosion resistance is inferior. In addition, the boron carbide is a material that is difficult to process due to its hardness, so that it is very difficult to process the shape and surface properties to a state suitable for the to-be-processed substrate, and a problem also arises in that the cost is also increased.

The present invention is conceived to solve the above problems and an object thereof is to provide a semiconductor manufacturing member which is capable of easily obtaining a processed shape in a semiconductor manufacturing member made of boron carbide as a material, and particularly, is excellent in corrosion resistance even in a reaction with oxygen plasma, and a manufacturing method therefor.

A semiconductor manufacturing member according to the present invention made to solve the above problems is characterized in that the semiconductor manufacturing member includes a silicon carbide-containing boron carbide film at least on a surface thereof, in which the silicon carbide-containing boron carbide film has a content of silicon carbide of 5 wt % or more and 18 wt % or less and a balance being boron carbide.

It is desirable that the film has a porosity of 5% or less.

In addition, it is desirable that the film is formed on a surface of a base material including silicon.

As described above, since the semiconductor manufacturing member of the present invention includes a silicon carbide-containing boron carbide film containing 5 wt % or more and 18 wt % or less of silicon carbide on at least the surface thereof, corrosion resistance to oxygen plasma and Ar plasma is improved. In addition, by reducing the porosity to 5% or less, a surface area exposed to the plasma can be reduced, and thus, the damage can be further reduced. In addition, when the base material of the semiconductor manufacturing member is made of silicon, the base material can be precisely processed by an existing silicon manufacturing technology. For this reason, since the shape and surface property of the base material made of silicon are controlled, it is possible to easily form a shape such as a focus ring without much post-processing.

In addition, a method of manufacturing the semiconductor manufacturing member according to the present invention made to solve the above problems is characterized in that the method includes:

preparing a raw material including silicon carbide and boron carbide; and

thermally spraying the raw material onto a base material to form a thermal-sprayed film including boron carbide including 5 wt % or more and 18 wt % or less of silicon carbide.

The base material may be removed from the semiconductor manufacturing member to form a semiconductor manufacturing member having only a film.

As described above, since the surface of the semiconductor manufacturing member of the present invention has a thermal-sprayed film made of boron carbide including 5 wt % or more and 18 wt % or less of silicon carbide, the corrosion resistance to oxygen plasma and Ar plasma can be improved. In addition, when the base material of the semiconductor manufacturing member is made of silicon, since an existing silicon manufacturing technology can be used for the base material itself, a precisely processed shape such as a focus ring can be easily made.

According to the present invention, it is possible to provide a semiconductor manufacturing member which is capable of easily obtaining a processed shape in a semiconductor manufacturing member made of boron carbide as a material, and particularly, is excellent in corrosion resistance even in a reaction with oxygen plasma, and a manufacturing method therefor.

### BRIEF DESCRIPTION OF DRAWINGS

FIG. 1 is a cross-sectional view schematically illustrating a configuration of a semiconductor manufacturing member.

FIG. 2A is a modification of the semiconductor manufacturing member of FIG. 1.

FIG. 2B is a modification of the semiconductor manufacturing member of FIG. 1.

FIG. 3 is a graph showing results of Examples and Comparative Examples of the present invention with respect to a sputtered amount of Ar.

FIG. 4 is a graph showing results of Examples and Comparative Examples of the present invention with respect to a consumed amount of oxygen plasma.

FIG. 5 is a graph showing results of Examples and Comparative Examples of the present invention with respect to a consumed amount of fluorine plasma.

### DESCRIPTION OF EMBODIMENTS

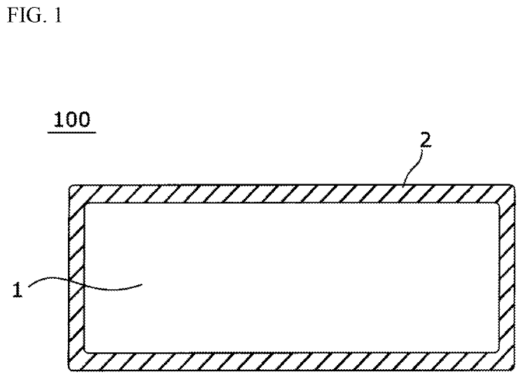

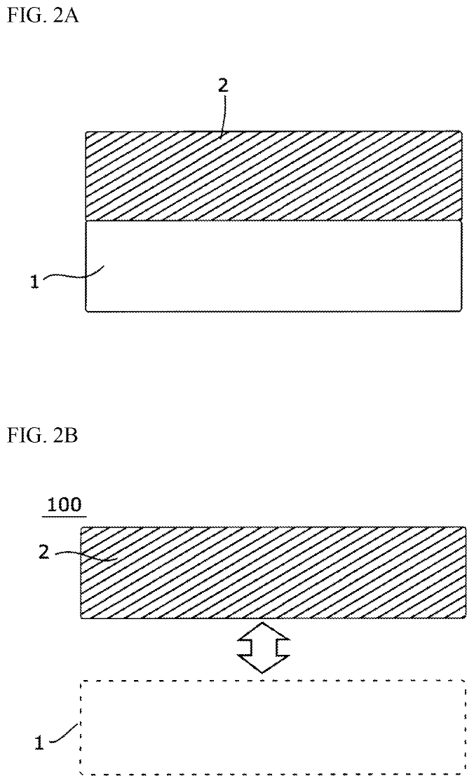

Hereinafter, embodiments according to the present invention will be described with reference to FIGS. 1, 2A, and 2B. The present invention is not limited to the embodiments described below. As FIG. 1 is a cross-sectional view schematically illustrating a configuration of a semiconductor manufacturing member and FIGS. 2A and 2B illustrate modifications of the semiconductor manufacturing member of FIG. 1, dimension relationship of elements, ratios of the elements, and the like are different from actual ones.

A semiconductor manufacturing member 100 illustrated in the drawing is configured with a base material 1 and a silicon carbide-containing boron carbide film 2 formed so as to cover a surface of the base material 1.

The base material 1 may be any material having plasma resistance, and for example, silicon and alumina are suitable. In particular, when silicon is used as the base material 1, for example, in the case of forming a focus ring as the semiconductor manufacturing member 100, shape processing thereof can be easily performed by using existing techniques and apparatuses.

The silicon carbide-containing boron carbide film 2 is formed to have a thickness of, for example, 500 μm. The content of silicon carbide (SiC) in the silicon carbide-containing boron carbide film 2 is 5 wt % or more and 18 wt % or less. The silicon carbide is desirably contained at more than 5 wt %, and more preferably contained at 6 wt % or more and 10 wt % or less.

When the content of silicon carbide is less than 5 wt %, the corrosion resistance effect to the oxygen plasma is reduced, which is not preferable.

On the other hand, when the content of silicon carbide is 5 wt % or more and up to 18 wt %, the corrosion resistance to oxygen plasma is improved. When the content of silicon carbide exceeds 18 wt %, further corrosion resistance effect cannot be expected.

For Ar plasma, since Ar+ ions are sputtered due to physical corrosion, the corrosion resistance is related to the strength of atomic bonds.

Since silicon carbide has a smaller atomic bond than boron carbide, as the added amount relatively increases, the sputtering rate increases, and thus, the corrosion resistance decreases. When the content of silicon carbide is 18 wt % or less, the corrosion resistance increases, and when the content of silicon carbide is less than 5 wt %, the corrosion resistance does not change substantially.

The content of silicon carbide has almost no effect on the fluorine plasma.

In addition, in the dry etching process in semiconductor manufacturing, the processes used in the plasma atmosphere of a single gas are limited, and thus, in many cases, interaction occurs in the plasma atmosphere of a mixed gas. Considering an advanced process in which a very high frequency power is applied, it is more preferable that the content of silicon carbide for obtaining a stable corrosion resistance effect is 6 wt % or more and 10 wt % or less.

The silicon carbide-containing boron carbide film 2 is preferably formed by thermal spraying, but may be formed by a CVD method or a PVD method by adjusting the composition ratio of boron carbide and silicon carbide.

While the CVD method can easily form a high-purity film, the thermal-sprayed film has a feature that the film can be easily formed on various substrates.

In the embodiment illustrated in FIG. 1, the silicon carbide-containing boron carbide film 2 is configured to be formed on the surface of the base material 1, but by forming the silicon carbide-containing boron carbide film 2 to be thick on the upper surface of the base material 1 as illustrated in FIG. 2A and by removing the base material 1 as illustrated in FIG. 2B, the semiconductor manufacturing member 100 including only the silicon carbide-containing boron carbide film 2 may be formed.

In addition, when the silicon carbide-containing boron carbide film 2 is a thermal-sprayed film, the temperature and collision rate of the raw material particles deposited on the base material 1 in the film forming process by thermal spraying become important factors that determine the density of the film and the adhesion to the base material 1.

In the present invention, the temperature and collision rate of the raw material particles are not limited, but in the case of forming, a thermal spraying method according to the physical properties of a to-be-coated material and the application thereof may be employed. For example, since boron carbide has a high melting point of 2763° C. and is oxidized under an oxygen atmosphere, a reduced pressure plasma spraying method or an electromagnetically accelerated plasma spraying method is preferable.

The sublimation temperature of silicon carbide is 2545° C. to 2730° C. which is lower than the melting point of boron carbide of 2763° C., and thus the silicon carbide is usually volatilized during the thermal spraying. For this reason, depending on the thermal spraying method, it is necessary to adjust the particle size and the mixing amount of silicon carbide, and the silicon carbide has a structure dispersed as particles in the thermal-sprayed film.

As described above, according to the embodiment of the present invention, since the silicon carbide-containing boron carbide film 2 is formed on the base material 1, and 5 wt % or more and 18 wt % or less, more preferably 6 wt % or more and 10 wt % or less of silicon carbide is contained in boron carbide, it is possible to improve the corrosion resistance to oxygen plasma and Ar plasma.

In addition, when the base material 1 includes silicon, since an existing manufacturing technique can be used, shape processing of a semiconductor manufacturing member such as a focus ring can be easily performed.

### EXAMPLE

The semiconductor manufacturing member and the manufacturing method therefor according to the present invention will be further described based on Examples.

### Example 1

In Example 1, a silicon carbide-containing boron carbide (B₄C) film having a thickness of 500 μm was formed onto a silicon substrate by thermal spraying to prepare a sample. A content of silicon carbide (SiC) in a boron carbide film after thermal spraying was set to 5 wt %. In the measurement of the silicon carbide content of the silicon carbide-containing boron carbide film, the silicon substrate was polished and removed, the remaining silicon substrate was melted and removed using an acid, and only the silicon carbide-containing boron carbide film was taken out. Then, the amount of boron and silicon was detected by ICP-MS, and the amount of SiC was calculated from the ratio. A surface after the thermal spraying was mirror-finished.

Further, the porosity of the silicon carbide-containing boron carbide film, which was observed with an optical microscope and was calculated by image editing software, was 3.9%.

The sputter rate for Ar ions was measured for the sample. The measurement conditions were that an Ar ion beam capable of generating high energy was used, a voltage was set to 3 kV, a beam current was set to 25 μA, and an irradiation time was set to 3 hours. Then, a sputtered consumed amount was measured.

### Example 2

In Example 2, a content of silicon carbide in a silicon carbide-containing boron carbide film of a sample was set to 7 wt %. Other conditions are the same as those in Example 1. The porosity of the silicon carbide-containing boron carbide film was 4.1%. Similarly to Example 1, for this sample, the sputter rate for Ar ions was measured.

### Example 3

In Example 3, a content of silicon carbide in a silicon carbide-containing boron carbide film of a sample was set to 18 wt %. Other conditions are the same as those in Example 1. The porosity of the silicon carbide-containing boron carbide film was 5.0%. Similarly to Example 1, for this sample, the sputter rate for Ar ions was measured.

### Comparative Example 1

In Comparative Example 1, a content of silicon carbide in a silicon carbide-containing boron carbide film of a sample was set to 0 wt %. Other conditions are the same as those in Example 1. The porosity of the boron carbide film was 3.5%. Similarly to Example 1, for this sample, the sputter rate for Ar ions was measured.

### Comparative Example 2

In Comparative Example 2, a silicon carbide film (100%) having a thickness of 500 μm was formed on a silicon substrate by a CVD method to prepare a sample. Other conditions are the same as those in Example 1. The porosity of the silicon carbide film was 0%. Similarly to Example 1, for this sample, the sputter rate for Ar ions was measured.

### Comparative Example 3

In Comparative Example 3, a silicon substrate having no film formed on a surface was used as a sample. Other conditions are the same as those in Example 1. Similarly to Example 1, for this sample, the sputter rate for Ar ions was measured.

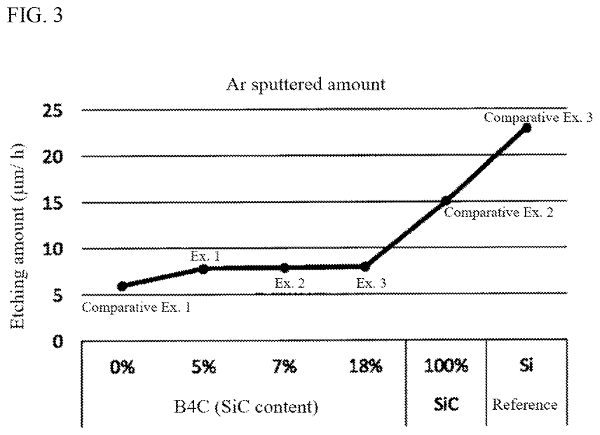

The graph of FIG. 3 shows the results of Examples 1, 2, and 3, and Comparative Examples 1, 2, and 3. In the graph of FIG. 3, the vertical axis is the etching amount (μm/h).

As shown in the graph of FIG. 3, it was found that the etching amount was suppressed by forming the silicon carbide-containing boron carbide film on the silicon surface (Comparative Example 1, Examples 1, 2, and 3).

### Example 4

The etching rate for oxygen plasma was measured for the sample prepared by the same method as that in Example 1. In the measurement of the etching rate for oxygen plasma, the sample was exposed to the oxygen plasma under a reduced pressure of 2.66 Pa at a high frequency power of 800 W, O₂=50 sccm, and at 200° C. for 30 minutes by using an ICP plasma etching apparatus. Then, the consumed amount was measured.

### Example 5

The same experiment as that in Example 4 was performed on the sample prepared by the same method as that in Example 2.

### Example 6

The same experiment as that in Example 4 was performed on the sample prepared by the same method as that in Example 3.

### Comparative Example 4

The experiment of Example 4 was performed on the sample prepared by the same method as that in Comparative Example 1.

### Comparative Example 5

The experiment of Example 4 was performed on the sample prepared by the same method as that in Comparative Example 2.

### Comparative Example 6

The experiment of Example 4 was performed on the sample prepared by the same method as that in Comparative Example 3.

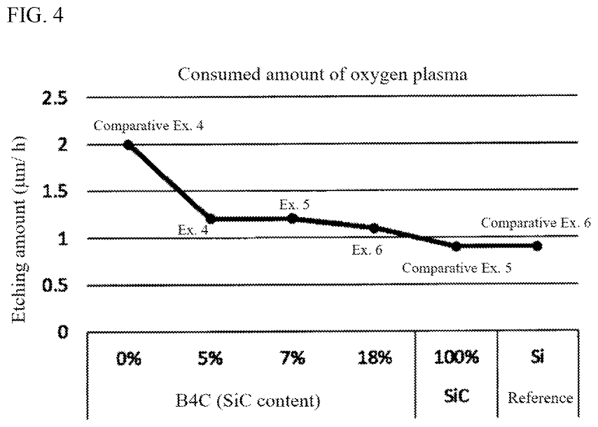

The graph of FIG. 4 shows the results of Examples 4, 5, and 6, and Comparative Examples 4, 5, and 6. In the graph of FIG. 4, the vertical axis is the etching amount (μm/h).

As shown in the graph of FIG. 4, it was found that, when the boron carbide film was formed on the silicon surface, etching amount was suppressed by setting the content of silicon carbide to 5% (Example 4), 7% (Example 5), and 18% (Example 6).

### Example 7

The etching rate for fluorine plasma was measured for the sample prepared by the same method as that in Example 1. In the measurement of the etching rate for fluorine plasma, the sample was exposed to the fluorine plasma under a reduced pressure of 2.66 Pa at a high frequency power of 500 W/bias power of 40 W, CF₄=100 sccm, and at room temperature for 4 hours by using an ICP plasma etching apparatus. Then, the consumed amount was measured.

### Example 8

The experiment of Example 7 was performed on the sample prepared by the same method as that in Example 2.

### Example 9

The experiment of Example 7 was performed on the sample prepared by the same method as that in Example 3.

### Comparative Example 7

The experiment of Example 7 was performed on the sample prepared by the same method as that in Comparative Example 1.

### Comparative Example 8

The experiment of Example 7 was performed on the sample prepared by the same method as that in Comparative Example 2.

### Comparative Example 9

The experiment of Example 7 was performed on the sample prepared by the same method as that in Comparative Example 3.

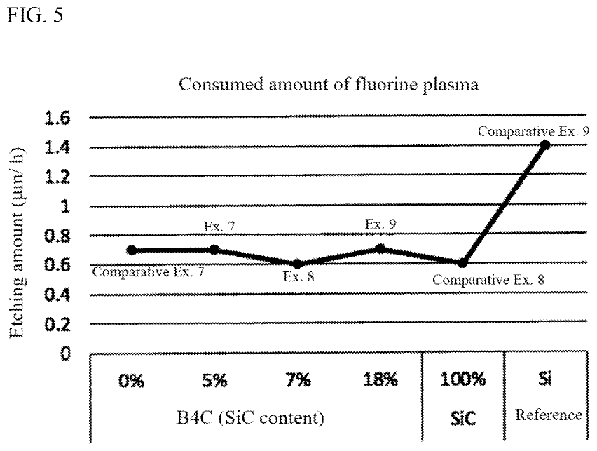

The graph of FIG. 5 shows the results of Examples 7, 8, and 9, and Comparative Examples 7, 8, and 9. In the graph of FIG. 5, the vertical axis is the etching amount (μm/h).

As shown in the graph of FIG. 5, no difference in effectiveness was admitted when the boron carbide film, silicon carbide film and boron carbide film changing in the content of silicon carbide were formed on the silicon surface.

### Example 10

The semiconductor manufacturing member was manufactured by the same method as that in Example 1. However, the thermal-sprayed film was thickened up to 2.0 mm, and then the silicon substrate was polished and removed. When the same experiments as those in Examples 1, 4, and 7 were performed, the corrosion resistance to various plasmas was the same as those in Examples 1, 4, and 7.

### Comparative Example 10

The semiconductor manufacturing member was manufactured by the same method as that in Example 1. However, the thickness of the thermal-sprayed film was changed to 100 μm, 200 μm, and 300 μm. As a result, at thicknesses of 100 μm and 200 μm, the thermal-sprayed film was slightly non-uniform and the porosity was about 10 to 20%. At a thickness of 300 μm, the thermal-sprayed film was formed to be almost uniform, and the porosity was 5% or less.

As a result of Examples 1 to 10 above, it was confirmed that the corrosion resistance to the Ar plasma and the oxygen plasma can be improved by the content of silicon carbide in the boron carbide film at 5 wt % or more and 18 wt % or less. In particular, it was found that the effect is great when the content of silicon carbide in the boron carbide film is 6 wt % or more and 10 wt % or less.

Although the preferred embodiment of the present invention has been described above, the present invention is not limited to the above-described embodiments, and various design changes can be made in the limitation disclosed in the claims. This application is based on and claims the benefit of priority from Japanese Patent Application No. 2020-144771, filed Aug. 28, 2020, and Japanese Patent Application No. 2021-097822, filed Jun. 11, 2021, the entire contents of which are incorporated herein by reference.
1 Base material
2 Silicon carbide-containing boron carbide film
100 Semiconductor manufacturing member

1. A semiconductor manufacturing member comprising a silicon carbide-containing boron carbide film at least on a surface thereof,
wherein the silicon carbide-containing boron carbide film has a content of silicon carbide of 5 wt % or more and 18 wt % or less and a balance being boron carbide.

2. The semiconductor manufacturing member according to claim 1, wherein the silicon carbide-containing boron carbide film has a porosity of 5% or less.

3. The semiconductor manufacturing member according to claim 1, wherein the silicon carbide-containing boron carbide film is formed on a surface of a base material comprising silicon.

4. The semiconductor manufacturing member according to claim 2, wherein the silicon carbide-containing boron carbide film is formed on a surface of a base material comprising silicon.

5. A method of manufacturing a semiconductor manufacturing member comprising:
preparing a raw material comprising silicon carbide and boron carbide; and
thermally spraying the raw material onto a base material to form a thermal-sprayed film comprising boron carbide comprising 5 wt % or more and 18 wt % or less of silicon carbide.

6. The method of manufacturing a semiconductor manufacturing member according to claim 5, further comprising removing the base material.
